(19) United States
(12) Patent Application Publication
(10) Pub. No.: US 2026/0314487 A1
(43) Pub. Date: Oct. 8, 2026

(54) COMPUTING SYSTEMS INCORPORATING HIGH-BANDWIDTH RRAM STACKS

(71) Applicant: TetraMem Inc., Fremont, CA (US)

(72) Inventors: Ning Ge, Danville, CA (US); Minxian Zhang, Amherst, MA (US)

(73) Assignee: TetraMem Inc., Fremont, CA (US)

(21) Appl. No.: 19/171,114

(22) Filed: Apr. 4, 2025

(51) Int. Cl. H01L 25/18; H01L 23/00; H01L 23/538; H10B 63/00; H10B 80/00; H10D 80/30

(52) U.S. Cl. CPC H10W 90/00; H10B 63/80; H10B 80/00; H10D 80/30; H10W 70/60; H10W 70/611; H10W 72/0198; H10W 90/297; H10W 90/722; H10W 90/724

(57) ABSTRACT

The present disclosure provides for computing systems incorporating high bandwidth in-memory computing stacks. A computing system may include a processing die and an RRAM stack connected to an interposer. The RRAM stack may include a plurality of vertically stacked RRAM dies for performing non-volatile memory, multi-level memory, and/or in-memory computing. Each of the RRAM dies may include one or more crossbar arrays configured to perform non-volatile memory and/or in-memory computing. Each of the plurality of crossbar arrays may include a plurality of bit lines, a plurality of word lines, and a plurality of cross-point devices at intersections of the plurality of word lines and the plurality of bit lines. In some embodiments, the computing system may further include vertically stacked dynamic random-access memory (DRAM) arrays and/or flash memory arrays.

### TECHNICAL FIELD

The implementations of the disclosure relate generally to computing systems and, more specifically, to computing systems incorporating high-bandwidth RRAM stacks for high-performance computing and/or in-memory computing applications with high-energy efficiency.

### BACKGROUND

Artificial intelligence (AI) systems typically operate in two stages. The first stage, known as training or teaching, may involve instructing a neural network (e.g., a convolutional neural network (CNN), deep neural network (DNN), etc.) to learn from examples rather than being explicitly programmed. Factors that influence the training process include the training data, the chosen algorithm, and the availability of high-performance computing resources such as GPUs and sufficient memory. The second stage is inference (or prediction), during which the inference system can use lower-performance chips than those required for the training stage. Existing AI systems typically include on-chip memory, such as SRAM, that stores data being actively processed and an off-chip DRAM memory that stores the larger dataset. Notably, significant time consumption and power consumption may occur during data transfer between processors and off-chip memory.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a computing system is provided. The computing system may include a processing die connected to an interposer; and a first resistive random-access memory (RRAM) stack connected to the interposer, wherein the first RRAM stack includes: a logic die connected to the interposer, a first plurality of RRAM dies vertically stacked on the logic die, wherein each of the first plurality of RRAM dies includes one or more crossbar arrays configured to perform at least one of non-volatile memory or in-memory computing, and wherein each of the plurality of crossbar arrays includes a plurality of bit lines, a plurality of word lines, and a plurality of RRAM devices at intersections of the plurality of word lines and the plurality of bit lines.

In some embodiments, the first plurality of vertically stacked RRAM dies is configured to implement a neural network, wherein a first RRAM die of the first plurality of vertically stacked RRAM dies receives an input analog signal, and wherein a second RRAM die of the first plurality of vertically stacked RRAM dies produces an output analog signal representing a processing result of the input analog signal after being processed by the neural network.

In some embodiments, the input analog signal corresponds to sensing signals produced by a plurality of sensors.

In some embodiments, the neural network is a convolutional neural network or a deep neural network.

In some embodiments, the logic die is connected to the interposer through a first physical layer block.

In some embodiments, the logic die is connected to the second RRAM die through a plurality of interconnects.

In some embodiments, the logic die includes an analog-to-digital converter that converts the output analog signal into a digital signal.

In some embodiments, the analog-to-digital converter further provides the digital signal to the processing die through the first physical layer block.

In some embodiments, the processing die is connected to the interposer through a second physical layer block.

In some embodiments, the first RRAM die includes a digital-to-analog converter.

In some embodiments, the processing die includes at least one of a central processing unit (CPU), a graphics processing unit (GPU), or an application-specific integrated circuit (ASIC) for performing machine learning.

In some embodiments, adjacent RRAM dies of the first plurality of RRAM dies are connected through a plurality of interconnects, wherein the plurality of interconnects includes through-silicon vias (TSVs).

In some embodiments, the plurality of interconnects further includes a plurality of micro-bumps.

In some embodiments, the computing system further includes a plurality of vertically stacked HBM (High-Bandwidth Memory) dies connected to the processing die, wherein each of the plurality of vertically stacked HBM dies includes DRAM (dynamic random-access memory) devices, and wherein the HBM dies are configured to perform low-latency processing of data-intensive operations.

In some embodiments, the computing system further includes a plurality of stacked HBF (High-Bandwidth Flash) dies, wherein each of the HBF dies includes flash memory devices.

In some embodiments, the first plurality of vertically stacked RRAM dies is configured to perform non-volatile memory, in-memory computing, and deep neural network processing, wherein the plurality of stacked HBM dies is configured to store frequently accessed data or weights of a neural network, and wherein the plurality of stacked HBF dies is configured to store high-volume less-frequently-accessed data or weights of the neural network.

In some embodiments, the computing system further includes a second plurality of vertically stacked RRAM dies connected to the interposer.

According to one or more aspects of the present disclosure, a method is provided. The method includes bonding a first resistive random-access memory (RRAM) wafer and a second RRAM wafer to form a wafer stack, wherein each of the first RRAM wafer and the second RRAM wafer includes one or more crossbar arrays configured to perform non-volatile memory and in-memory computing. Each of the one or more crossbar arrays includes a plurality of bit lines, a plurality of word lines, and a plurality of RRAM devices at intersections of the plurality of word lines and the plurality of bit lines; and dicing the wafer stack into a plurality of RRAM dies.

In some embodiments, the method further includes forming a die underfill between the bonded first RRAM wafer and the second RRAM wafer.

In some embodiments, bonding the first RRAM wafer and the second RRAM wafer includes: fabricating a plurality of through-silicon vias (TSVs) in the first RRAM wafer and the second RRAM wafer; fabricating micro-pads on the plurality of TSVs; and bonding the first RRAM wafer and the second RRAM wafer through the micro-bumps.

### BRIEF DESCRIPTION OF THE DRAWINGS

The disclosure will be more fully understood from the detailed description given below and from the accompanying drawings of various embodiments of the disclosure. The drawings, however, should not be taken to limit the disclosure to the specific embodiments, but are for explanation and understanding.

FIGS. 1A and 1B are schematic diagrams illustrating a side view and a top view of an example computing system incorporating resistive random-access memory (RRAM) stacks in accordance with some embodiments of the present disclosure.

FIG. 2 is a diagram illustrating an example of a crossbar array in accordance with some embodiments of the present disclosure.

FIG. 3 is a schematic diagram illustrating a perspective view of an example RRAM die stack in accordance with some embodiments of the present disclosure.

FIG. 4 is a schematic diagram illustrating a cross-sectional view of an example of an RRAM die stack in accordance with some embodiments of the present disclosure.

FIG. 5 is a flowchart illustrating an example process for fabricating an RRAM die stack in accordance with some embodiments of the present disclosure.

FIG. 6 is a schematic diagram illustrating a High-Performance Computing (HPC) system incorporating RRAM stacks in accordance with some embodiments of the present disclosure.

FIG. 7 is a schematic diagram illustrating an HPC system incorporating RRAM stacks and dynamic random-access memory (DRAM) stacks in accordance with some embodiments of the present disclosure.

FIG. 8 is a schematic diagram illustrating an HPC system incorporating RRAM stacks and flash memory stacks in accordance with some embodiments of the present disclosure.

FIG. 9 is a schematic diagram illustrating an HPC system incorporating RRAM stacks, DRAM stacks, and flash memory stacks in accordance with some embodiments of the present disclosure.

### DETAILED DESCRIPTION

Aspects of the disclosure provide computing systems incorporating high-bandwidth RRAM stacks. A computing system may include a central processing unit (CPU), a memory unit, interconnections between the memory and the CPU, and input and output (I/O) devices. The data movement between the memory and CPU may often limit the performance of the computing system (referred to as the von Neumann bottleneck) as the CPU has to wait for the memory unit or the I/O unit to transfer data. A significant amount of time and energy may be spent on data movement. To overcome the von Neumann bottleneck, high-bandwidth or stacked memory may be used, where multiple layers of memory chips are vertically stacked on top of each other and then connected with each other before connecting them to the logic chip. A high-performance computing (HPC) system with RRAM stacks may be used for non-volatile memory or in-memory computing applications. In some embodiments, a computing system may include a processing die and an RRAM stack connected to an interposer. In some embodiments, the interposer may be connected to a packaging substrate. The processing die may include a central processing unit (CPU), a graphics processing unit (GPU), an application-specific integrated circuit (ASIC), etc. for performing machine learning operations (e.g., training, inference, etc.). The RRAM stack may include a plurality of vertically stacked RRAM dies for performing memory (non-volatile) and computing operations. Each of the RRAM dies may include one or more crossbar arrays of RRAM devices and/or any other suitable memory devices for performing non-volatile memory and/or in-memory computing. For example, the RRAM dies may implement a neural network, such as a convolutional neural network (CNN) or a deep neural network (DNN), where a first RRAM die (e.g., the uppermost RRAM die) receives inputs to be processed by the neural network and another RRAM die (e.g., the bottommost RRAM die) produces analog outputs representing outputs of the neural network. The RRAM dies may be stacked on a logic die that may convert the analog outputs from the RRAM dies into digital signals, process these digitized signals, and provide inputs for the processing die through through-silicon vias (TSVs) and/or a physical layer (PHY) interface. The logic die and the processing die may be connected to the interposer through respective physical layer interface (PHY) blocks.

The computing system architecture disclosed herein may significantly reduce the data travel distance between the memory and the processor, which in turn lowers latency and diminishes processing loads on both the logic die and the processing die. Moreover, they may offer higher bandwidth, faster data transfer rates, and a wider memory interface. The computing systems described herein may be used to implement edge AI (artificial intelligence), which refers to the deployment of artificial intelligence algorithms and data processing directly on edge devices or end devices (e.g., smartphones, sensors, or autonomous vehicles) rather than in remote cloud servers, thereby further reducing latency by processing data locally. The computing systems described herein are highly power-efficient, operating at low power and featuring low standby power due to their non-volatile memory design, resulting in lower hardware and operational costs, while enhancing data security by processing data locally and thus protecting users'sensitive and/or confidential information from network-based vulnerabilities. The computing systems can function offline, ensuring continued operation even during network outages or intermittent connectivity. Additionally, they may further enable improved model accuracy, as machine-learning models can be continuously refined and become more accurate with training on increasing volumes of data.

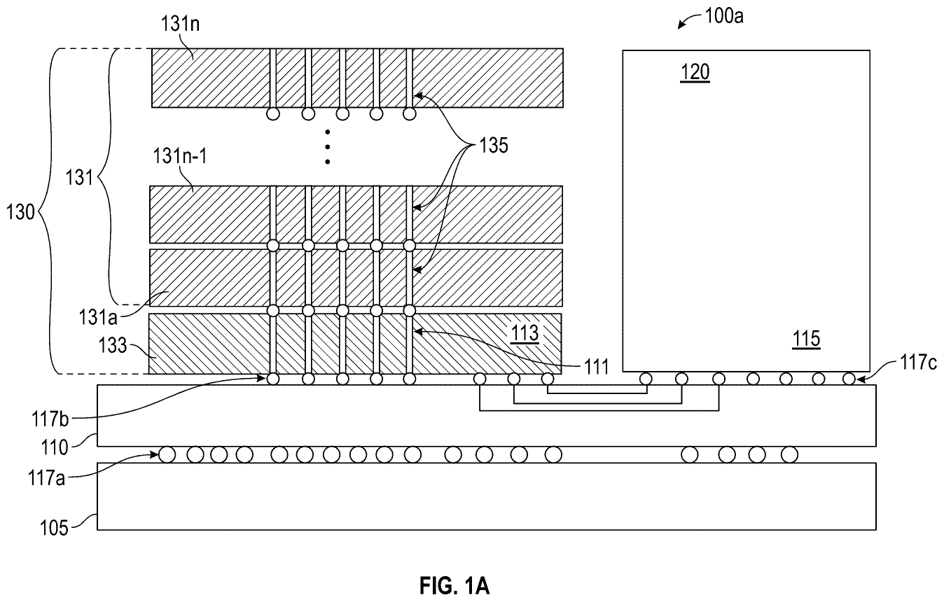

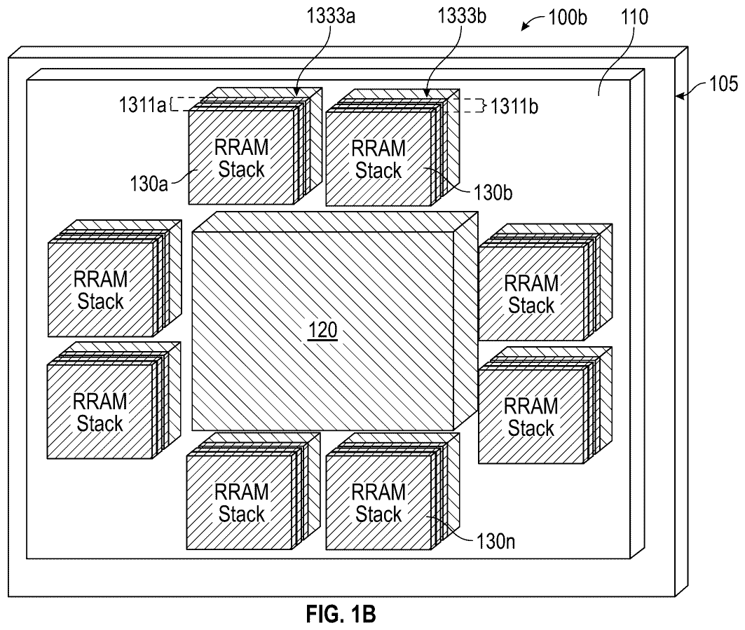

FIGS. 1A and 1B are schematic diagrams illustrating a side view and a top view of an example computing system for performing machine learning in accordance with some embodiments of the present disclosure.

As shown in FIG. 1A, computing system 100a may include a processing die 120 and a high-bandwidth RRAM stack 130 connected to and mounted on an interposer 110. RRAM stack 130 may be connected to interposer 110 through TSVs (through-silicon vias) 111 and/or a physical (PHY) block 113 (also referred to as “the first PHY block”). Processing die 120 may be connected to interposer 110 through a physical (PHY) block 115 (also referred to as the “second PHY block”).

The PHY (physical layer interface) blocks 113 and 115 may function as a physical interface circuitry configured to handle the electrical signaling between RRAM stack 130 and processing die 120. PHY blocks 113 and 115 may ensure proper data transmission and reception between the different dies by managing signal timing, voltage levels, and other physical layer aspects.

Interposer 110 may be connected to a packaging substrate 105 through bump 117a. RRAM stack 130, TSVs 111, and PHY block 113 may further be electrically and mechanically connected to interposer 110 through micro-bumps 117b. Processing die 120 and block 115 may be further connected to interposer 110 through micro-bumps 117c. Bumps 117a and 117b may include conductive materials (e.g., tin-based solder alloys to connect copper pillars). Bumps 117a, 117b, and 117c may function as die-to-die interconnects providing electrical connectivity and mechanical stability between the RRAM stack 130, processing die 120, and interposer 110, enabling high-speed and low-latency data transmission within the computing system.

Interposer 110 may be a silicon substrate, which contains dense interconnection lines to ensure high-bandwidth and low-latency data transmission. The silicon interposer is configured to provide a sufficient surface area for mounting and interconnecting the dies. This design may enable high-speed, low-latency communication and data transfer between processing die 120 and RRAM stack 130 by providing dedicated interconnect pathways that efficiently route signals and power. It may also allow for finer-pitch connections between the dies compared to a standard package substrate (not shown in FIG. 1A).

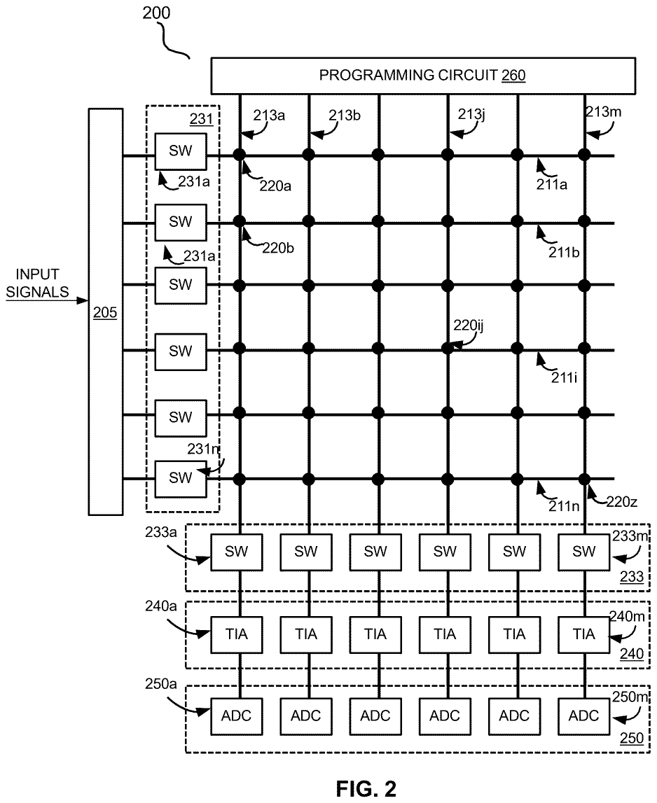

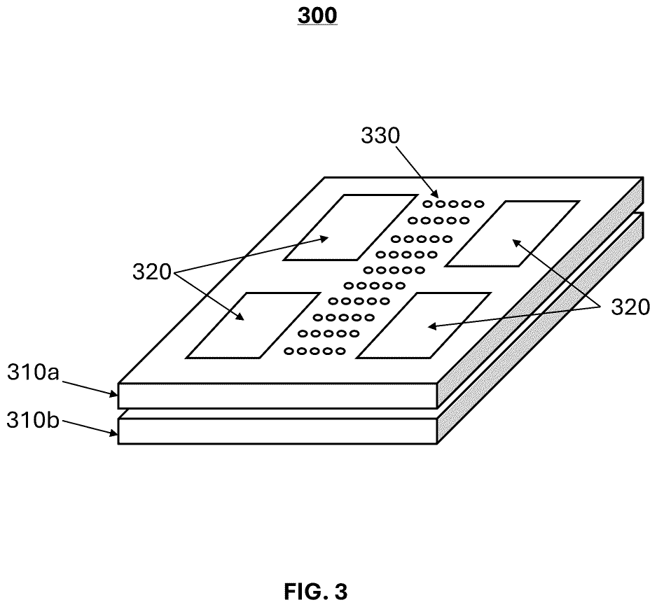

RRAM stack 130 may include multiple RRAM dies 131a, . . . 131n (collectively referred to as the “RRAM dies 131”) and one or more logic dies 133. As shown, RRAM dies 131 may be vertically stacked on logic die 133. Each RRAM die 131a, . . . 131n may include one or more crossbar arrays that may perform both memory (non-volatile) and computing functions. Each of the crossbar arrays may include a plurality of interconnecting electrically conductive wires (e.g., row wires, column wires, etc.), integrated circuits, and cross-point devices fabricated at the intersections of the electrically conductive wires configured to perform parallel analog multiplication and summation operations. The cross-point devices may include, for example, resistive random-access memory (RRAM) devices, phase-change memory devices, floating gates, spintronic devices, and/or any other suitable devices with programmable resistance. In some embodiments, each RRAM die 131a, . . . 131n may include one or more crossbar arrays as described in connection with FIGS. 2-3 below.

As an example, a crossbar array may receive an input voltage signal V and may produce an output current signal I. The relationship between the input voltage signal and the output current signal may be represented as I=VG, wherein G represents the conductance values of the cross-point devices. As such, the input signal may be weighted at each of the cross-point devices by its conductance value according to Ohm's law. The weighted currents output via each bit line may be accumulated according to Kirchhoff's current law. The conductance values of the cross-point devices may be programmed to values and/or weights representative of one or more matrices used for implementing a neural network or a portion of the neural network. The crossbar array may produce analog output signals (e.g., current signals) representing the processing results of the input voltage signal by the matrix.

In some embodiments, RRAM dies 131 may implement a neural network that executes machine learning algorithms. The neural network may include multiple convolutional layers, each of which may perform certain convolution operations (e.g., 2D convolution, depth-wise convolution, etc.). Each layer of the neural network may be implemented using one or more crossbar arrays. For example, one or more first crossbar arrays may implement a first layer (e.g., an input layer) of the neural network. The first crossbar array(s) may receive an analog input and perform one or more convolution operations on the analog input. In some embodiments, the analog input may correspond to analog sensing signals produced by one or more sensors, such as image sensors, audio sensors, infrared sensors, thermal sensors, LiDAR sensors, radar sensors, inertial sensors, etc. Performing a convolution operation on the analog sensing data may involve applying one or more kernels to different portions of the analog input. For example, a 2D convolution may be performed by applying a single convolution kernel to the analog input. More particularly, the convolution kernel may be used to scan each part of the analog input with the same size as the convolution kernel to produce a convolution result. As another example, performing a depth-wise convolution on the sensing data may involve convolving each channel of the analog input with a respective kernel and stacking the convolved outputs together. For example, the conductance values of a plurality of cross-point devices in the first crossbar array(s) may be programmed to values that represent a 2D convolution kernel. The first crossbar array(s) may output a current signal representing a convolution of the analog input and the 2D convolution kernel. In some embodiments, the crossbar array(s) may store multiple 2D convolution kernels by mapping each of the 2D convolution kernels to a plurality of cross-point devices of the first crossbar array(s). The first crossbar array(s) may output a plurality of output signals (e.g., current signals) representative of the convolution results. The outputs of the first crossbar array(s) may be provided as inputs to one or more second crossbar arrays implementing a subsequent neural network layer for further processing. The outputs of the second crossbar arrays may be provided as inputs to additional crossbar arrays implementing subsequent neural network layers (e.g., additional hidden layers) for further processing. The outputs of the second crossbar arrays may be provided to one or more crossbar arrays implementing a subsequent layer of the neural network (e.g., a second hidden layer) for processing. One or more third crossbar arrays may implement an output layer of the neural network. The outputs of the third crossbar arrays (e.g., analog current signals) may represent the output of the neural network. In some embodiments, the topmost RRAM die (e.g., RRAM die 131n) may receive the analog input representing signals to be processed by the neural network and implement the input layer of the neural network. The bottommost RRAM die (e.g., RRAM die 131a) may produce an analog output representing the output of the neural network (i.e., the result of processing the analog input). In some embodiments, the neural network may be implemented using crossbar arrays as disclosed in U.S. patent application Ser. No. 16/125,454, entitled “Implementing a Multi-Layer Neural Network Using Crossbar Array,” which is incorporated herein by reference in its entirety. In some embodiments, the crossbar arrays may implement a deep neural network (DNN) configured to execute machine learning algorithms.

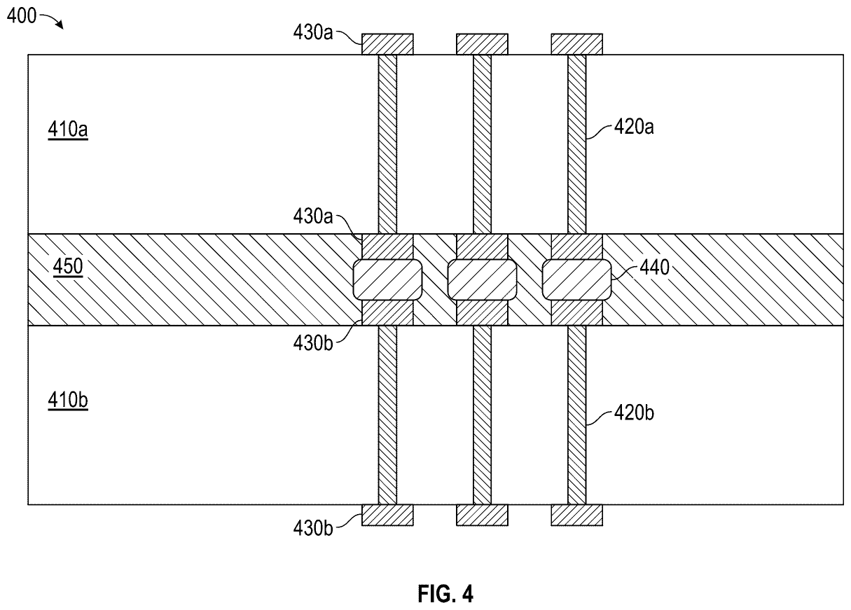

The vertically stacked RRAM dies 131 may be connected through interconnects 135. Interconnects 135 may include TSVs, micro-bumps (e.g., solder bumps) connecting TSVs between adjacent RRAM dies, etc. that may create physical and electrical connections between adjacent RRAM dies. Interconnects 135 may enable fast vertical data transmission through RRAM dies 131 and RRAM stack 130. In some embodiments, adjacent RRAM dies 131 may be interconnected as described in connection with FIG. 4 below.

Logic die 133 may contain logic circuitry configured to control and manage RRAM dies 131 and function as an interface between processing die 120 and RRAM dies 131. For example, logic die 133 may handle memory requests, data transfers, and other control functions for RRAM stack 130. In some embodiments, logic die 133 may include analog-to-digital converter (ADC) circuits that may convert the analog output produced by RRAM dies 131 into digital signals, process the digital signals, and/or provide the digital signals to processing die 120 through TSVs and/or PHY blocks.

Processing die 120 may include one or more central processing units (CPUs), graphics processing units (GPUs), system-on-chip (SoC) devices, application-specific integrated circuits (ASICs) designed for specialized and efficient processing, and/or other suitable hardware processors and/or circuitry that may perform machine-learning operations (e.g., training machine learning models and/or performing inference using trained machine learning models). For example, processing die 120 may generate a predictive output by running a trained machine-learning model using the output provided by RRAM dies 131. The predictive output may represent, for example, a classification result (e.g., a class label assigned to the sensing data), a decision derived from the machine-learning model, or a natural-language response generated by a large language model (LLM). The machine-learning model may refer to a model artifact created by processing die 120 using training data that includes known training inputs and corresponding known outputs (e.g., correct answers associated with respective training inputs). Processing die 120 may identify patterns in the training data that map the known inputs to the known outputs (the outputs to be predicted), thereby producing a machine-learning model capable of capturing these patterns for various tasks, including traditional classification and advanced natural-language understanding and generation.

The machine-learning models may include models composed of a single level of linear or non-linear operations (e.g., support vector machines), neural networks composed of multiple levels of non-linear operations, and advanced transformer-based architecture designed for processing sequential data. The neural network may include an input layer, one or more hidden layers, and an output layer. The neural network may be trained, for example, by adjusting the weights in accordance with a backpropagation learning algorithm or similar techniques. As an example, the machine learning models may include transformer-based LLMs. An LLM architecture may include an embedding layer configured to convert input tokens into vector representations, which are subsequently combined with positional encodings to capture the order of tokens. The LLM architecture may further include multiple transformer blocks, each integrating multi-head self-attention mechanisms with residual connections and layer normalization, along with feed-forward networks. An output softmax layer may generate a probability distribution over tokens for prediction.

Referring to FIG. 1B, computing system 100b illustrates a top view of computing system 100a. Computing system 100b may include processing die 120 and a plurality of RRAM stacks 130a, 130b, . . . 130n fabricated on interposer 110 and mounted on a packaging substrate 105. Each of RRAM stacks 130a, 130b, . . . 130n may include an RRAM stack 130 described in connection with FIG. 1A above. For example, a first RRAM stack 130a may include a first plurality of RRAM dies 1311a vertically stacked on a first logic die 1333a. A second RRAM stack 130b may include a second plurality of RRAM dies 1311b stacked on a second logic die 1333b. The first plurality of RRAM dies 1311a and the second plurality of RRAM dies 1311b may include RRAM dies 131a-131n as described in connection with FIG. 1A. The first logic die 1333a and the second logic die 1333b may be the logic die 133 as described in connection with FIG. 1A.

RRAM stacks 130a, 130b, . . . 130n may each include vertically stacked RRAM dies that may perform non-volatile memory operations, ensuring data retention even when power is removed. The RRAM stacks may operate in an analog mode, enabling specialized computations. Their in-memory computing functionality reduces data movement and enhances performance. Furthermore, by supporting parallel processing, these stacks facilitate multilayer neural network processing, making them well-suited for complex AI workloads. They also combine low-power operation with fast data transfer and rapid response times, leading to increased throughput and overall efficiency.

FIG. 2 is a diagram illustrating an example 200 of a crossbar array in accordance with some embodiments of the present disclosure. As shown, crossbar array 200 may include a plurality of interconnecting electrically conductive wires, such as one or more row wires 211a, 211b, . . . 211i, . . . 211n, and column wires 213a, 213b, . . . 213j, . . . 213m for an n-row by m-column crossbar array. The crossbar array 200 may further include cross-point devices 220a, 220b, . . . 220z, etc. Each of the cross-point devices may connect to a row wire and a column wire. For example, the cross-point device 220ij may connect the row wire 211i and the column wire 213j. The number of the column wires 213a-m and the number of the row wires 211a-n may or may not be the same. Crossbar array 200 may further include a word line (WL) logic 205 that is connected to the cross-point devices via the row wires 211a-n. The WL logic 205 may include any suitable component for applying input signals to selected cross-point devices via row wires 211a-n, such as one or more digital-to-analog converters (DACs), amplifiers, etc. Each of the input signals may be a voltage signal, a current signal, etc. The input signals may correspond to the analog sensing signals produced by various sensors (not shown).

Row wires 211a-n may include a first row wire 211a, a second row wire 211b,. 211i, . . . and an n-th row wire 211n. Each of row wires 211a, . . . 211n may be and/or include any suitable electrically conductive material. In some embodiments, each row wire 211a-n may be a metal wire.

Column wires 213a-m may include a first column wire 213a, a second column wire 213b, . . . and an m-th column wire 213m. Each column wire 213a-m may be and/or include any suitable electrically conductive material. In some embodiments, each column wire 213a-m may be a metal wire.

Each cross-point device 220 may be and/or include any suitable device with tunable resistance, such as a memristor, phase-change memory (PCM) devices, floating gates, spintronic devices, ferroelectric devices, RRAM devices, etc.

Each of row wires 211a-n may be connected to one or more row switches 231 (e.g., row switches 231a-231n). Each row switch 231 may include any suitable circuit structure that may control the current flowing through row wires 211a-211n. For example, row switches 231 may be and/or include a CMOS switch circuit.

Each of column wires 213a-m may be connected to one or more column switches 233 (e.g., switches 233a-233m). Each column switch 233a-233m may include any suitable circuit structure that may control the current that passes through column wires 213a-213m. For example, column switches 233a-233m may be and/or include a CMOS switch circuit. In some embodiments, one or more of switches 231a-231n and 233a-233m may further provide fault protection, electrostatic discharge (ESD) protection, noise reduction, and/or any other suitable function for one or more portions of crossbar array 200.

The output sensor(s) 240 may include any suitable component for converting the current flowing through column wires 213a-n into the output signal, such as one or more TIAs (trans-impedance amplifiers) 240a-m. Each TIA 240a-m may convert the current through a respective column wire into a respective voltage signal. Each ADC 250a-m may convert the voltage signal produced by its corresponding TIA into a digital output. In some embodiments, output sensor(s) 240 may further include one or more multiplexers (not shown).

The programming circuit 260 may program the cross-point devices 220 selected by switches 231 and/or 233 to suitable conductance values. For example, programming a cross-point device may involve applying a suitable voltage signal or current signal across the cross-point device. The resistance of each cross-point device may be electrically switched between a high-resistance state and a low-resistance state. Setting a cross-point device may involve switching the resistance of the cross-point from the high-resistance state to the low-resistance state. Resetting the cross-point device may involve switching the resistance of the cross-point from the low-resistance state to the high-resistance state.

Crossbar array 200 may perform parallel weighted voltage multiplication and current summation. For example, an input voltage signal may be applied to one or more rows of crossbar array 200 (e.g., one or more selected rows). The input signal may flow through the cross-point devices of the rows of the crossbar array 200. The conductance of the cross-point device may be tuned to a specific value (also referred to as a “weight”). By Ohm's law, the input voltage multiplies the cross-point conductance and generates a current from the cross-point device. By Kirchhoff's law, the summation of the current passing through the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is output via each column wire and may be accumulated according to Kirchhoff's current law. This may enable in-memory computing (IMC) via parallel multiplications and summations performed in the crossbar arrays.

Crossbar array 200 may be configured to perform vector-matrix multiplication (VMM). A VMM operation may be represented as Y=XA, wherein each of Y, X, A represents a respective matrix. More particularly, for example, input vector X may be mapped to the input voltage V of crossbar array 200. Matrix A may be mapped to conductance values G. The output current I may be read and mapped back to output results Y. In some embodiments, crossbar array 200 may be configured to implement a portion of a neural network by performing VMMs.

In some embodiments, crossbar array 200 may perform convolution operations. For example, performing 2D convolution on input data may involve applying a single convolution kernel to the input signals. Performing a depth-wise convolution on the input data may involve convolving each channel of the input data with a respective kernel corresponding to the channel and stacking the convolved outputs together. The convolution kernel may have a particular size defined by multiple dimensions (e.g., a width, a height, a channel, etc.). The convolution kernel may be applied to a portion of the input data having the same size to produce an output. The output may be mapped to an element of the convolution result that is located at a position corresponding to the position of the portion of the input data.

The programming circuit 260 may program the crossbar array 200 to store convolution kernels for performing 2D convolution operations. For example, a convolution kernel may be converted into a vector and mapped to a plurality of cross-point devices of the crossbar array that are connected to a given bit line. In particular, the conductance values of the cross-point devices may be programmed to values representative of the convolution kernel. In response to the input signals, the crossbar array 200 may output, via the given bit line, a current signal representative of a convolution of the input signals and the 2D convolution kernel. In some embodiments, crossbar array 200 may store multiple 2D convolution kernels by mapping each of the 2D convolution kernels to the cross-point devices connected to a respective bit line. Crossbar array 200 may output a plurality of output signals (e.g., current signals) representative of the convolution results via column wires 213.

FIG. 3 is a schematic diagram illustrating a perspective view of an example RRAM die stack 300 in accordance with some embodiments of the present disclosure.

As shown, RRAM die stack 300 may include RRAM dies 310a and 310b vertically stacked and interconnected by interconnects 330. Interconnects 330 may include TSVs, micro-bumps, and any other suitable vertical electrical interconnects that pass through the first RRAM die 310a and the second RRAM die 310b. Each of the RRAM dies 310a and 310b may include one or more arrays of RRAM devices. For example, one or more crossbar arrays 320 may be fabricated on the RRAM die 310a. Each of the crossbar arrays 320 may be and/or include a crossbar array 200 as described in connection with FIG. 2. The RRAM dies 310a and 310b may correspond to two adjacent RRAM dies 131 as described in connection with FIG. 1A. Interconnects 330 may correspond to interconnects 135 as described in connection with FIG. 1A.

FIG. 4 is a schematic diagram illustrating a cross-sectional view of an example 400 of a RRAM die stack in accordance with some embodiments of the present disclosure.

As shown, RRAM die stack 400 may include a first RRAM wafer 410a and a second RRAM wafer 410b vertically stacked and connected through TSVs 420a-420b, micro-pads 430a-430b, and solder micro-bumps 440. Each of the first RRAM wafer 410a and the second RRAM wafer 410b may include RRAM arrays and supporting circuitry. First RRAM wafer 410a and second RRAM wafer 410b may be mechanically coupled and protected by die underfill 450, which fills the gap between the wafers surrounding the micro-pads 430a-430b and solder micro-bumps 440 to enhance structural integrity and mitigate thermo-mechanical stress.

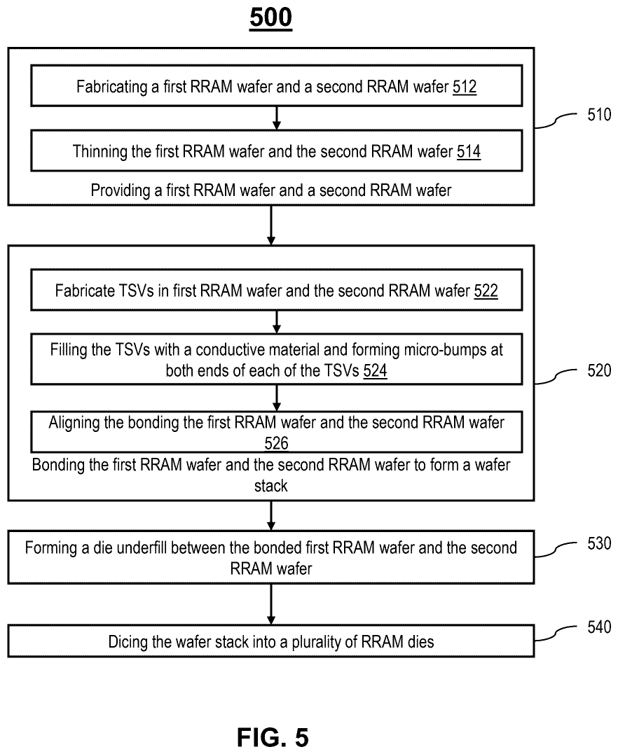

FIG. 5 is a flowchart illustrating an example process 500 for fabricating an RRAM die stack in accordance with some embodiments of the present disclosure. Process 500 may be carried out to fabricate RRAM die stack 400 as described in connection with FIG. 4.

At 510, a first RRAM wafer and a second RRAM wafer may be provided. For example, at 512, the first RRAM wafer and the second RRAM wafer may be fabricated. The first RRAM wafer and the second RRAM wafer may include RRAM arrays and supporting circuitry. At 514, the first RRAM wafer and the second RRAM wafer may be thinned from the backside to a suitable thickness (e.g., a thickness of less than 100 μm). In some embodiments, the thickness of the thinned first RRAM wafer and/or the thinned second RRAM wafer (e.g., RRAM wafers 410 a and 410 b of FIG. 4) may be around 40 to 60 μm.

At 520, the first RRAM wafer may be bonded to the second RRAM wafer to form a wafer stack. For example, at 522, through-silicon vias (TSVs) (e.g., TSVs 420a-420b of FIG. 4) may be fabricated in the first RRAM wafer and the second RRAM wafer. At 524, the TSVs may be filled with a conductive material (e.g., copper). In some embodiments, an insulating layer may be applied to the via sidewalls, and the conductive material may be deposited or electroplated to fill these vias, creating conductive vertical connections. Micro-pads (e.g., micro-pads 430a-430b) may be formed at both ends (on the top and bottom surfaces) of each of the TSVs. The micro-pads may include one or more conductive materials, such as copper, tin, etc. The micro-pads may be formed using deposition and patterning techniques such as electroplating or deposition onto the ends of the TSVs. At 526, the first RRAM wafer and the second RRAM wafer may then be aligned and bonded to each other, for example, using solder (e.g., solder 440 of FIG. 4) to form the wafer stack 400 as shown in FIG. 4. The solder may form electrical and mechanical connections between the micro-pads.

At 530, a die underfill may be formed between the bonded RRAM wafers. For example, an underfill material (die underfill 450 of FIG. 4) may be injected between the bonded RRAM wafers to reinforce the solder joints, improve mechanical reliability, and enhance thermal performance. The underfill material may be an epoxy-based compound or another type of polymer that may provide suitable adhesion, mechanical strength, and thermal conductivity.

At 540, the wafer stack may be diced into a plurality of RRAM dies. In particular, the wafer stack may be precisely diced along predefined scribe lines. Each individual die, contain-ing its own RRAM arrays, TSVs, micro-pads, and circuitry, may be ready for packaging and in-tegration into larger electronic systems, such as the RRAM stack 130 of FIG. 1A.

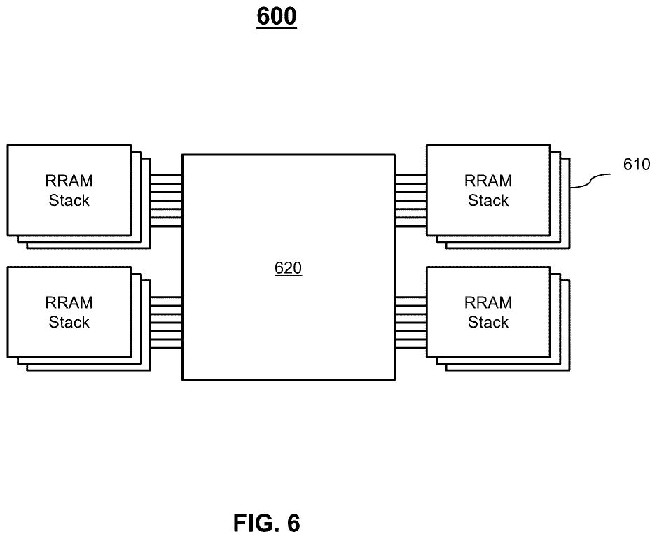

FIG. 6 illustrates a High-Performance Computing (HPC) system 600 using RRAM stacks to form high-bandwidth RRAM memory (HBRM). RRAM's non-volatility and its ability to store multibit weights via analog behavior allow it to be used for both memory and computation, thereby enabling massive parallel processing. Consequently, the RRAM stack is advantageous for multilayer neural network processing, offering low-power consumption, rapid data transfer, fast response times, high throughput, and enhanced overall efficiency.

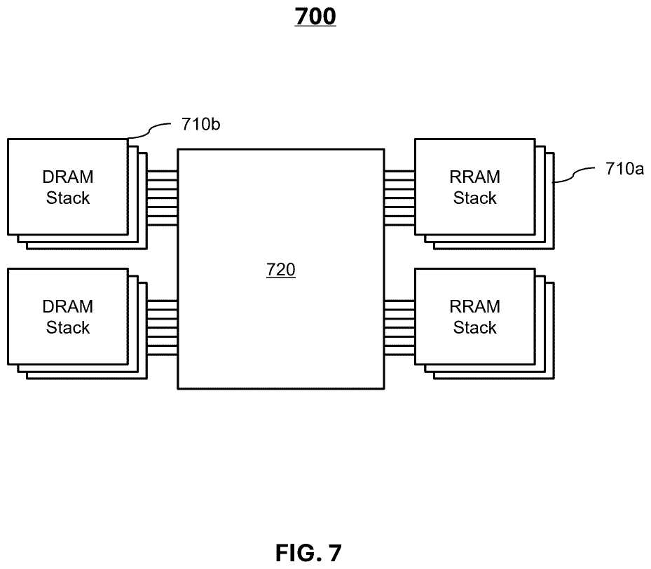

FIG. 7 is a schematic diagram illustrating a computing system 700 incorporating stacked RRAM dies and vertically stacked High Bandwidth Memory (HBM) dies in accordance with some embodiments of the present disclosure. As shown, computing system 700 may include one or more RRAM stacks 710a connected to a processing die 720. The processing die 720 may be the processing die 120 of FIG. 1. Each RRAM stack 710a may be the RRAM stack 130 of FIG. 1. System 700 may further include one or more DRAM stacks or HBM stacks 710b connected to the processing die 720. Each of the HBM stacks 710b may include stacked HBM dies. Each of the HBM dies may include DRAM devices. By leveraging stacked DRAM, HBM stacks 710b may offer low-latency processing for efficient handling of time-sensitive or data-intensive operations. By incorporating both RRAM dies and HBM dies, computing system 700 leverages the high-performance and energy-efficiency using HBM and RRAM stacks, making it especially suitable for edge applications demanding rapid response times, such as autonomous vehicles, robotics, and critical monitoring systems.

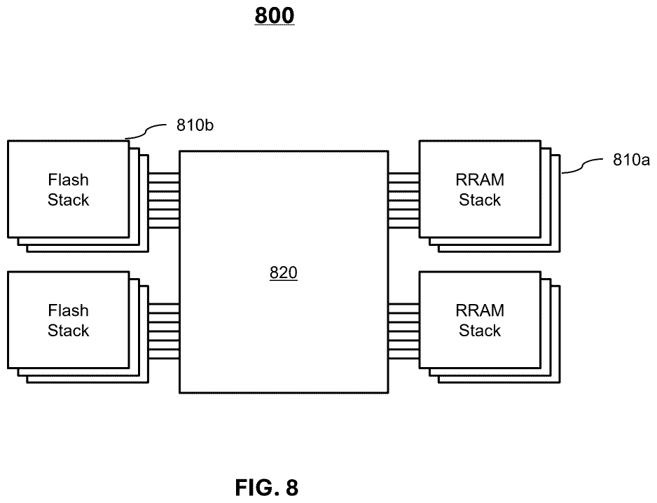

FIG. 8 is a schematic diagram illustrating a computing system 800 incorporating stacked RRAM dies and stacked flash memory. As shown, computing system 800 may include one or more RRAM stacks 810a connected to a processing die 820. The processing die 820 may be the processing die 120 of FIG. 1. Each of the RRAM stacks 810a may be the RRAM stack 130 of FIG. 1. The computing system 800 may further include one or more High-Bandwidth Flash (HBF) or Flash stacks 810b comprising vertically stacked HBF dies. Each of the HBF dies may include flash memory and supporting circuitry. The HBF dies may offer higher memory capacity at a relatively low cost, making them particularly well-suited for handling large volumes of data. The hybrid configuration comprising the RRAM stacks 810a and the HBF stacks may enable computing system 800 to efficiently process large datasets, especially in edge applications where a large volume of data is required while the ultra-low latency is not the strictest requirement.

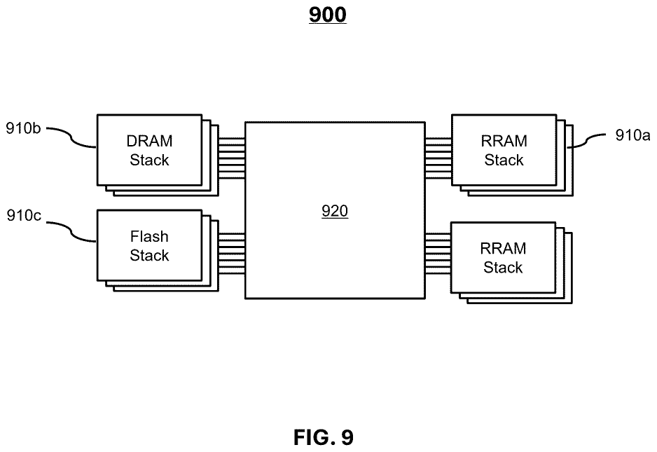

FIG. 9 is a schematic diagram illustrating a computing system 900 incorporating stacked RRAM dies, stacked HBM dies, and stacked HBF dies in accordance with some embodiments of the present disclosure. As shown, computing system 900 may include one or more RRAM stacks 910a connected to a processing die 920. The processing die 920 may be the processing die 120 of FIG. 1. Each of the RRAM stacks 910a may include an RRAM stack 130 of FIG. 1. Computing system 900 may further include one or more HBM stacks or DRAM stacks 910b connected to the processing die 920. Each of the HBM stacks 910b may include stacked HBM dies. The computing system 900 may further include one or more HBF stacks or flash stacks 910c, each comprising stacked HBF dies. The RRAM dies may be dedicated to in-memory computing and deep neural network processing as described above. Meanwhile, HBM dies may store more active data or weights requiring rapid access. HBF dies may store large-volume but less-active data or weights, providing a balanced approach that maximizes performance and cost-effectiveness.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A computing system, comprising:
a processing die connected to an interposer; and
a first resistive random-access memory (RRAM) stack connected to the interposer, wherein the first RRAM stack comprises:
a first plurality of vertically stacked RRAM dies, wherein each of the first plurality of vertically stacked RRAM dies comprises one or more crossbar arrays configured to perform at least one of non-volatile memory or in-memory computing, and wherein each of the plurality of crossbar arrays comprises a plurality of bit lines, a plurality of word lines, and a plurality of RRAM devices at intersections of the plurality of word lines and the plurality of bit lines.

2. The computing system of claim 1, wherein the first plurality of vertically stacked RRAM dies are configured to implement a neural network, wherein a first RRAM die of the first plurality of vertically stacked RRAM dies receives an input analog signal, and wherein a second RRAM die of the first plurality of vertically stacked RRAM dies produces an output analog signal representing a processing result of the input analog signal after being processed by the neural network.

3. The computing system of claim 2, wherein the input analog signal corresponds to sensing signals produced by a plurality of sensors.

4. The computing system of claim 2, wherein the neural network is a convolutional neural network or a deep neural network.

5. The computing system of claim 2, wherein the first plurality of vertically stacked RRAM dies is vertically stacked on a logic die, and wherein the logic die is connected to the interposer through a first physical layer block.

6. The computing system of claim 5, wherein the logic die is connected to the second RRAM die through a plurality of interconnects.

7. The computing system of claim 5, wherein the logic die comprises an analog-to-digital converter that converts the output analog signal into a digital signal.

8. The computing system of claim 7, wherein the analog-to-digital converter further provides the digital signal to the processing die through the first physical layer block.

9. The computing system of claim 5, wherein the processing die is connected to the interposer through a second physical layer block.

10. The computing system of claim 5, wherein the first RRAM die comprises a digital-to-analog converter.

11. The computing system of claim 1, wherein the processing die comprises at least one of a central processing unit, a graphics processing unit, or an application-specific integrated circuit for performing machine learning.

12. The computing system of claim 1, wherein adjacent RRAM dies of the first plurality of RRAM dies are connected through a plurality of interconnects, wherein the plurality of interconnects comprises through-silicon vias (TSVs).

13. The computing system of claim 12, wherein the plurality of interconnects further comprises a plurality of micro-bumps.

14. The computing system of claim 1, further comprising a plurality of vertically stacked HBM (High-Bandwidth Memory) dies connected to the processing die, wherein each of the plurality of vertically stacked HBM dies comprises DRAM (dynamic random-access memory) devices, and wherein the HBM dies are configured to perform low-latency processing of time sensitive or data-intensive operations.

15. The computing system of claim 14, further comprising a plurality of stacked HBF (High-Bandwidth Flash) dies, wherein each of the HBF dies comprises flash memory devices.

16. The computing system of claim 15, wherein the first plurality of vertically stacked RRAM dies is configured to perform non-volatile memory, multi-level memory, in-memory computing and deep neural network processing, wherein the plurality of stacked HBM dies are configured to store frequently accessed data or weights of a neural network, and wherein the plurality of stacked HBF dies are configured to store high volume less frequently accessed data or weights of the neural network.

17. The computing system of claim 1, further comprising a second plurality of vertically stacked RRAM dies connected to the interposer.

18. A method, comprising:
bonding a first resistive random-access memory (RRAM) wafer and a second RRAM wafer to form a wafer stack, wherein each of the first RRAM wafer and the second RRAM wafer comprises one or more crossbar arrays configured to perform non-volatile memory, multi-level memory, and in-memory computing operations, and wherein each of the one or more crossbar arrays comprises a plurality of bit lines, a plurality of word lines, and a plurality of RRAM devices at intersections of the plurality of word lines and the plurality of bit lines; and
dicing the wafer stack into a plurality of RRAM dies.

19. The method of claim 18, further comprising forming a die underfill between the bonded first RRAM wafer and the second RRAM wafer.

20. The method of claim 18, wherein bonding the first RRAM wafer and the second RRAM wafer comprises:
fabricating a plurality of through-silicon vias (TSVs) in the first RRAM wafer and the second RRAM wafer;
fabricating micro-pads on the plurality of TSVs; and
bonding the first RRAM wafer and the second RRAM wafer through the micro-pads.
